(19) United States
(12) Patent Application Publication
(10) Pub. No.: US 2005/0082556 A1
(43) Pub. Date: Apr. 21, 2005

(54) InGaN-based led

(76) Inventors: Ying-Che Sung, Dashi (TW); Pan-Tzu Chang, Dashi (TW); Li-Min Hsu, Dashi (TW); Wen-Huang Tseng, Dashi (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/914,206

(22) Filed: Aug. 10, 2004

(30) Foreign Application Priority Data
Oct. 16, 2003 (TW) 092218383

(51) Int. Cl. H01L 27/15

(52) U.S. Cl. 257/96

(57) ABSTRACT

A blue LED epitaxial wafer grown on an Al₂O₃ substrate, the blue LED epitaxial wafer having a contact electrode on the bottom side after removal of the Al₂O₃ substrate, conducting terminals formed on the top side, and a substitute substrate selected from chrome, tungsten, molybdenum, copper, copper chrome alloy, copper molybdenum alloy, copper tungsten alloy, molybdenum tungsten alloy, or their combination alloy and bonded to the top side and connected to the conducting terminals.

### BACKGROUND OF THE INVENTION

a. Field of the Invention

The present invention relates to light emitting diodes and, more particularly, to an InGaN-based LED that uses a substitute substrate of high conductivity in heat and electricity to substitute for an Al₂O₃ sapphire substrate so as to improve heat dissipation efficiency and to let the LED be made in vertical.

b. Description of the Related Art

GaN III-V series compound semiconductors are mainly based on InGaN, AlGaN, or AlGaInN. Currently, the most efficient substrates for growing GaN III-V series compound semiconductor are Al₂O₃ substrates. However, Al₂O₃ substrates are not electrically conductive. When using an Al₂O₃ substrate to make an InGaN-based LED, as shown in FIG. 1, it is to deposit an epitaxial wafer 1 on an Al₂O₃ sapphire substrate 2, which epitaxial wafer 1 is comprised in proper order a GaN crystal-growing layer 11, an n-type GaN buffer layer 12, an n-type AlGaN cladding layer 13, a multi-quantum well InGaN light generating (active) layer 14, and a p-type AlGaN cladding layer 15, and a p-type GaN contact layer 16. Because the Al₂O₃ sapphire substrate 2 is not electrically conductive, the positive electrode and the negative electrode must be arranged on the same side. As shown in FIG. 2, the p-electrode 17 is formed on the top side of the p-type GaN contact layer 16, and the n-electrode 18 is formed on the n-type GaN buffer layer 12 after etching at the epitaxial wafer 1 to the n-type GaN buffer layer 12.

A blue LED made according to the aforesaid method is still not satisfactory in function. For example, because of poor heat dissipation nature of the Al₂O₃ sapphire substrate 2, heat cannot be removed efficiently from the epitaxial wafer 1 during operating, thereby causing the LED unable to stand high current. Due to this limitation, this design of blue LED does not provide high brightness and, is not durable in use. Further, because the p-electrode 17 and the n-electrode 18 are arranged on the same side, the LED cannot be made in vertical. Therefore, there are limitations on the fabrication and application of this electrode design of blue LED.

Therefore, it is desirable to provide an InGaN-based LED that eliminates the aforesaid drawbacks.

### SUMMARY OF THE INVENTION

The present invention has been accomplished under the circumstances in view. It is one object of the present invention to provide an InGaN-based LED, which uses a substitute substrate of high conductivity in heat and electricity to substitute for an Al₂O₃ sapphire temporary substrate so as to improve the brightness of the LED.

It is another object of the present invention to provide an InGaN-based LED, which is capable of receiving a high current, prolonging the service life.

It is still another object of the present invention to provide an InGaN-based LED, which can be made in a vertical form for convenient use.

To achieve these and other objects of the present invention, the InGaN-based LED comprises a blue LED epitaxial wafer grown on an Al₂O₃ substrate, at least one conducting terminal respectively formed on the top side; and a substitute substrate bonded to the top side of the blue LED epitaxial wafer and connected to the at least one conducting terminal. The substitute substrate is selected from chrome, tungsten, molybdenum, copper, copper chrome alloy, copper molybdenum alloy, copper tungsten alloy, molybdenum tungsten alloy, or their combination alloy; and said Al₂O₃ substrate is removed after a substitute substrate bonded to the top side of said blue LED epitaxial wafer, said blue LED epitaxial wafer having a bottom side from which said Al₂O₃ substrate is removed, a top side opposite to said bottom side, and a contact electrode formed on said bottom side.

### BRIEF DESCRIPTION OF THE DRAWINGS

FIG. 1 is a schematic drawing showing the formation of an InGaN-based LED according to the prior art.

FIG. 2 is a schematic structural view of an InGaN-based LED according to the prior art.

FIG. 3 is a schematic drawing showing the formation of an InGaN-based LED according to the present invention.

FIG. 4 is an exploded view of the present invention.

FIG. 5 is a schematic drawing showing removal of the crystal-growing substrate from the epitaxial wafer according to the present invention.

FIG. 6 is an assembly view of the present invention.

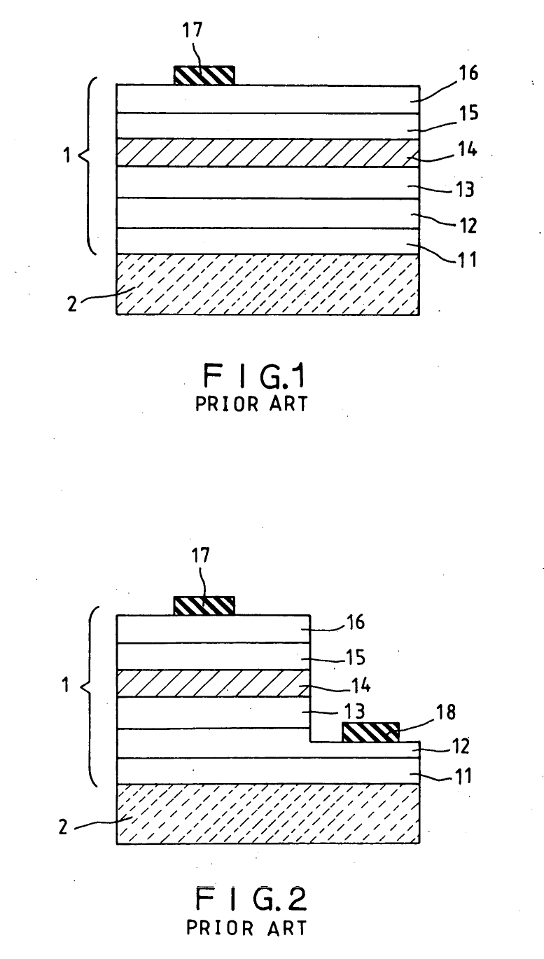

### DETAILED DESCRIPTION OF THE PREFERRED EMBODIMENTS

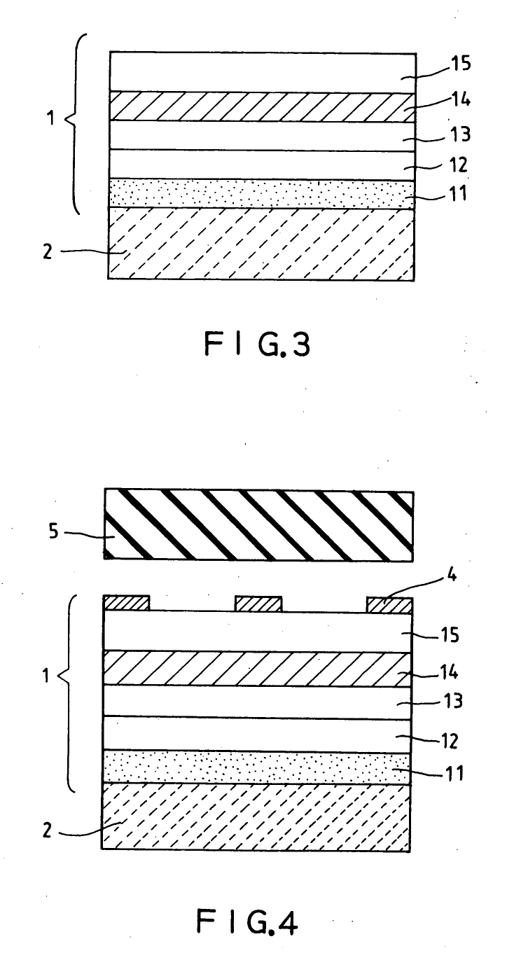

Referring to FIGS. 3 and 4, an LED (light emitting diode) in accordance with the present invention comprises a blue LED epitaxial wafer 1 grown on an Al₂O₃ substrate 2. The blue LED epitaxial wafer 1 is comprised of a GaN crystal-growing layer 11, an n-type GaN buffer layer 12, an n-type AlGaN cladding layer 13, a multi-quantum well InGaN light generating (active) layer 14, and a p-type AlGaN cladding layer 15.

Referring to FIG. 4, at least one conducting terminal 4 is formed on the top side of the epitaxial wafer 1, i.e., on the surface of the p-type AlGaN cladding layer 15. A number of small conducting terminals 4 can be formed on the top side of the epitaxial wafer 1 at different locations to reduce the problem of current jam.

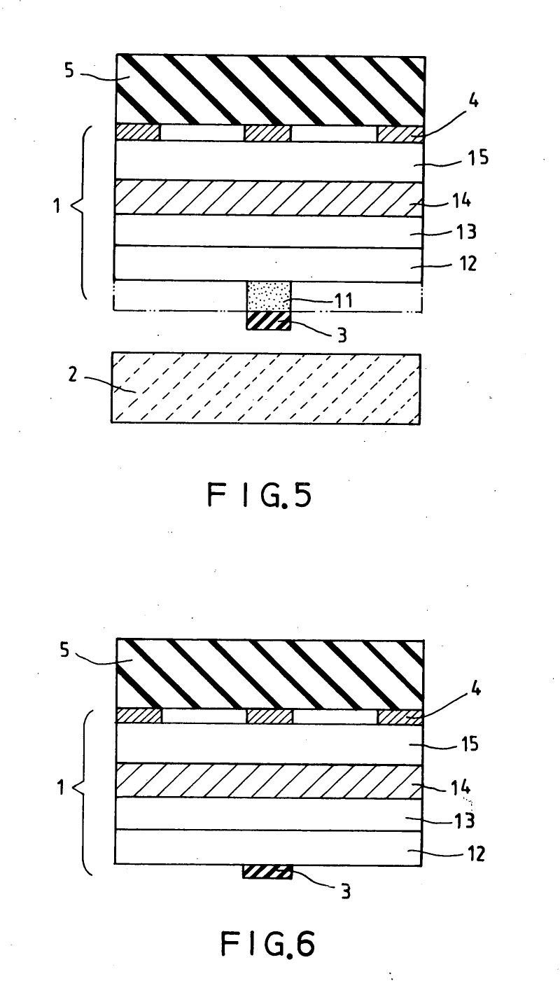

Referring to FIG. 5 and FIG. 4 again, a substitute substrate 5 is bonded to the top side of the epitaxial wafer 1 and connected to the conducting terminals 4. The substitute substrate 5 is selected from chrome(Cr), tungsten(W), molybdenum(Mo), copper(Cu), copper chrome alloy(Cu/Cr), copper molybdenum alloy(Cu/Mo), copper tungsten alloy(Cu/W), molybdenum tungsten alloy(Mo/W), or their combination alloy for the advantages of high heat and electric conductivity and good heat dissipation capability. Further, the thermal expansion coefficient of these materials is close to that of the epitaxial wafer 1.

The substitute substrate 5 is formed on the top side of the epitaxial wafer 1 is in consideration of the supporting force of the LED. According to test, the weaken bottom side of the epitaxial wafer 1 is not practical for the formation of the substitute substrate 5 due to technical problems. Therefore, the substitute substrate 5 is formed on the top side of the epitaxial wafer 1 and used as an external substrate to substitute for the Al₂O₃ substrate 2.

Referring to FIG. 5, after removal of the Al₂O₃ substrate 2 from the epitaxial wafer 1, an electrically conductive contact electrode 3 is formed on the surface (bottom side) of the GaN crystal-growing layer 11 of the epitaxial wafer 1. Because the GaN crystal-growing layer 11 absorbs photons, the other area of the GaN crystal-growing layer 11 except the contact electrode 3 is removed from the n-type GaN buffer layer 12.

Alternatively, the contact electrode 3 can be formed on the n-type GaN buffer layer 12 after removal of the GaN crystal-growing layer 11, as shown in FIG. 6.

As indicated above, the invention uses a substitute substrate 5 to substitute for the non-conductive Al₂O₃ substrate 2. Because the substitute substrate 5 has good heat and electricity conducting capability, the heat produced during operation of the LED can efficiently be dissipated. Therefore, a blue LED can be operated at high current about 3˜4 times over the conventional designs to enhance the brightness. According to tests, the invention increases about 30%˜50% of the brightness.

Further, due to good heat dissipation capability, the reliability and service life of the LED are relatively improved and prolonged. The present invention is practical for making a vertical LED of high brightness without having the drawbacks of the conventional designs.

Although particular embodiments of the present invention have been shown and described, it will be understood that various modifications and changes could be made thereunto without departing from the spirit and scope of the invention disclosed.

1. An InGaN-based LED (light emitting diode) comprising:
a blue LED epitaxial wafer grown on an Al₂O₃ substrate;
at least one conducting terminal respectively formed on the top side of said blue LED epitaxial wafer;
a substitute substrate bonded to the top side of said blue LED epitaxial wafer and connected to said at least one conducting terminal, said substitute substrate being selected from one of a group of materials including chrome(Cr), tungsten(W), molybdenum(Mo), copper(Cu), copper chrome alloy(Cu/Cr), copper molybdenum alloy(Cu/Mo), copper tungsten alloy(Cu/W), molybdenum tungsten alloy(Mo/W), and their combination alloy; and
said Al₂O₃ substrate is removed after a substitute substrate bonded to the top side of said blue LED epitaxial wafer, said blue LED epitaxial wafer having a bottom side from which said Al₂O₃ substrate is removed, a top side opposite to said bottom side, and a contact electrode formed on said bottom side.

2. The InGaN-based LED as claimed in claim 1, which is made in a vertical form.
